(19) United States
(12) Patent Application Publication
(10) Pub. No.: US 2026/0354259 A1
(43) Pub. Date: Nov. 5, 2026

(54) CHIP PACKAGE STRUCTURE WITH DIELECTRIC STRUCTURE AND METHOD FOR FORMING THE SAME

(71) Applicant: Taiwan Semiconductor Manufacturing Company, Ltd., Hsinchu (TW)

(72) Inventors: Chin-Ying TSAI, Hsinchu County (TW); Zhi-Wei ZHUANG, Zhudong, Hsinchu County (TW); Chien-Ying WU, Hsinchu City (TW); Tsung-Yang HSIEH, Taipei City (TW); Chia-Wen HSUEH, Hsinchu City (TW)

(21) Appl. No.: 19/194,450

(22) Filed: Apr. 30, 2025

(51) Int. Cl. H10W 74/10; H10W 20/20; H10W 72/20; H10W 74/01

(52) U.S. Cl. CPC H10W 74/147; H10W 20/20; H10W 74/01; H10W 74/111; H10W 72/244

(57) ABSTRACT

A method for forming a chip package structure is provided. The method includes providing a semiconductor substrate, a conductive via structure, and an insulating layer. The conductive via structure passes through the semiconductor substrate, the semiconductor substrate has a front surface and a back surface opposite to the front surface, the insulating layer is over the back surface, the semiconductor substrate has a base portion and a protruding portion over the base portion, and the protruding portion is between the conductive via structure and the insulating layer. The method includes converting the protruding portion into a dielectric structure. The method includes forming a conductive bump over the conductive via structure.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements.

Dozens or hundreds of integrated circuits are typically manufactured on a single semiconductor wafer. The individual dies are singulated by sawing the integrated circuits along scribe lines. The individual dies are then packaged separately. The semiconductor industry continues to improve the integration density of various electronic components (e.g., transistors, diodes, resistors, capacitors, etc.) by continual reductions in minimum feature size, which allow more components to be integrated into a given area. However, since feature sizes continue to decrease, fabrication processes continue to become more difficult to perform. Therefore, it is a challenge to form reliable packages with electronic components with high integration density.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A-1J are cross-sectional views of various stages of a process for forming a chip package structure, in accordance with some embodiments.

FIG. 1H-1 is a top view of the semiconductor device structure of FIG. 1H, in accordance with some embodiments.

FIG. 1I-1 is a top view of the semiconductor device structure of FIG. 1I, in accordance with some embodiments.

FIG. 2 is a cross-sectional view of a chip package structure, in accordance with some embodiments.

FIGS. 3A-3B are cross-sectional views of various stages of a process for forming a chip package structure, in accordance with some embodiments.

FIG. 4 is a cross-sectional view of a chip package structure, in accordance with some embodiments.

FIG. 5 is a cross-sectional view of a chip package structure, in accordance with some embodiments

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. The term “substantially” may be varied in different technologies and be in the deviation range understood by the skilled in the art. For example, the term “substantially” may also relate to 90% of what is specified or higher, such as 95% of what is specified or higher, especially 99% of what is specified or higher, including 100% of what is specified, though the present invention is not limited thereto. Furthermore, terms such as “substantially parallel” or “substantially perpendicular” may be interpreted as not to exclude insignificant deviation from the specified arrangement and may include for example deviations of up to 10°. The word “substantially” does not exclude “completely” e.g. a composition which is “substantially free” from Y may be completely free from Y.

The term “about” may be varied in different technologies and be in the deviation range understood by the skilled in the art. The term “about” in conjunction with a specific distance or size is to be interpreted so as not to exclude insignificant deviation from the specified distance or size. For example, the term “about” may include deviations of up to 10% of what is specified, though the present invention is not limited thereto. The term “about” in relation to a numerical value x may mean x±5 or 10% of what is specified, though the present invention is not limited thereto.

Some embodiments of the disclosure are described. Additional operations can be provided before, during, and/or after the stages described in these embodiments. Some of the stages that are described can be replaced or eliminated for different embodiments. Additional features can be added to the chip package structure. Some of the features described below can be replaced or eliminated for different embodiments. Although some embodiments are discussed with operations performed in a particular order, these operations may be performed in another logical order.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

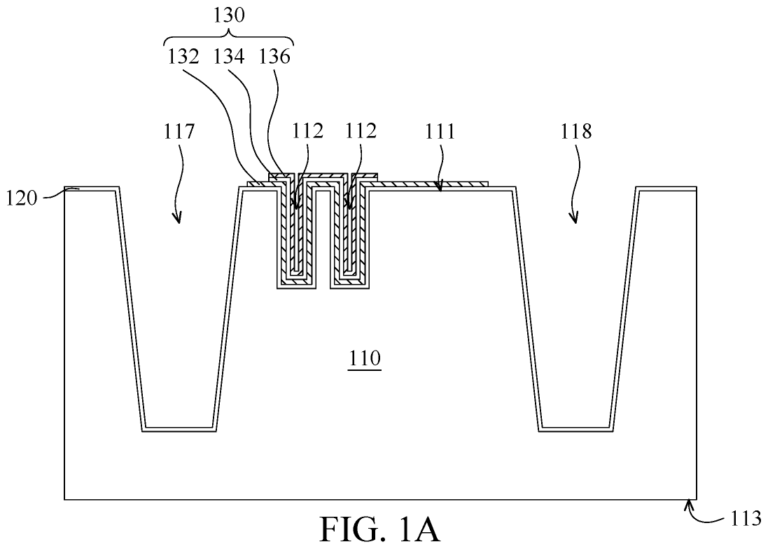

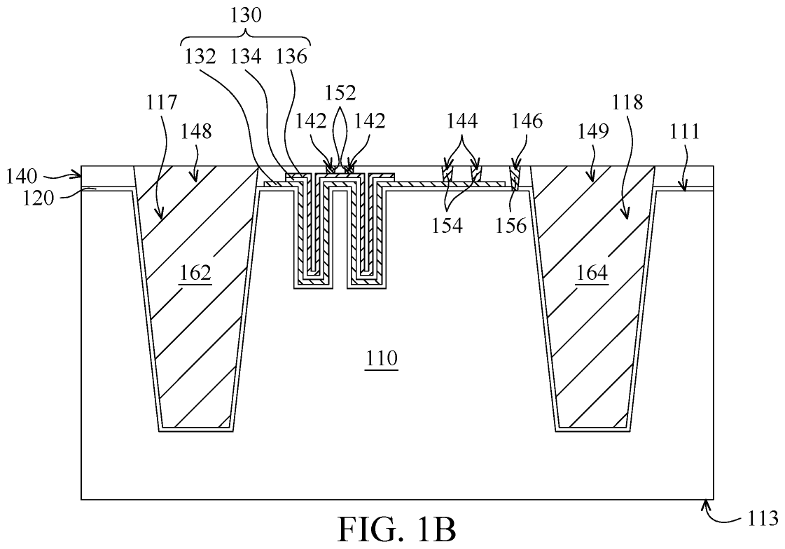

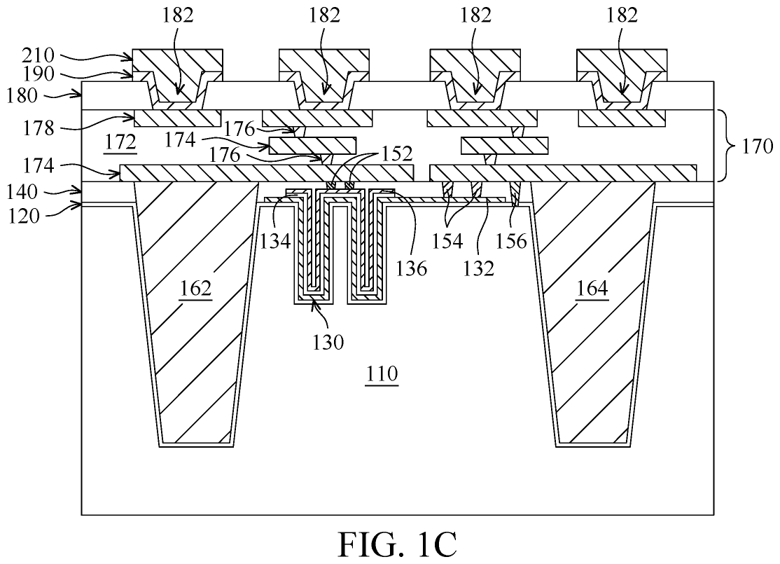

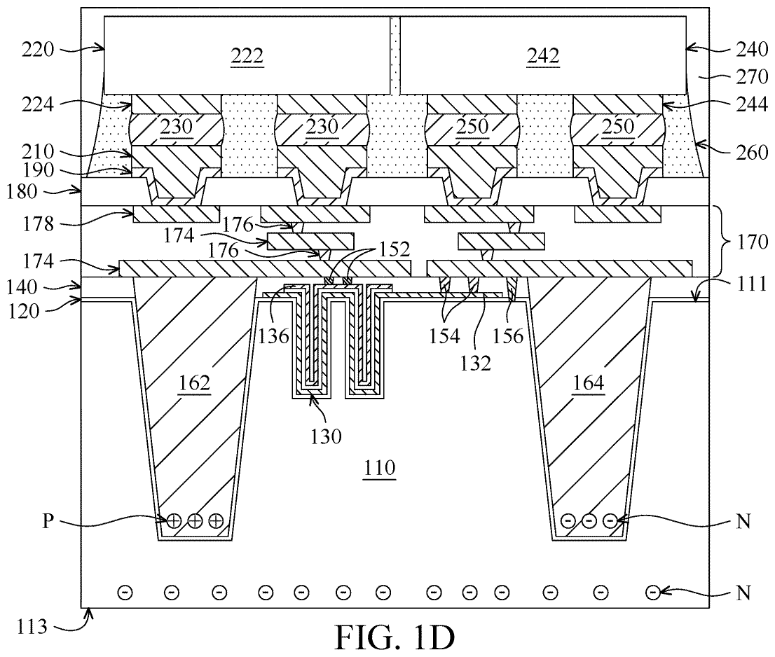

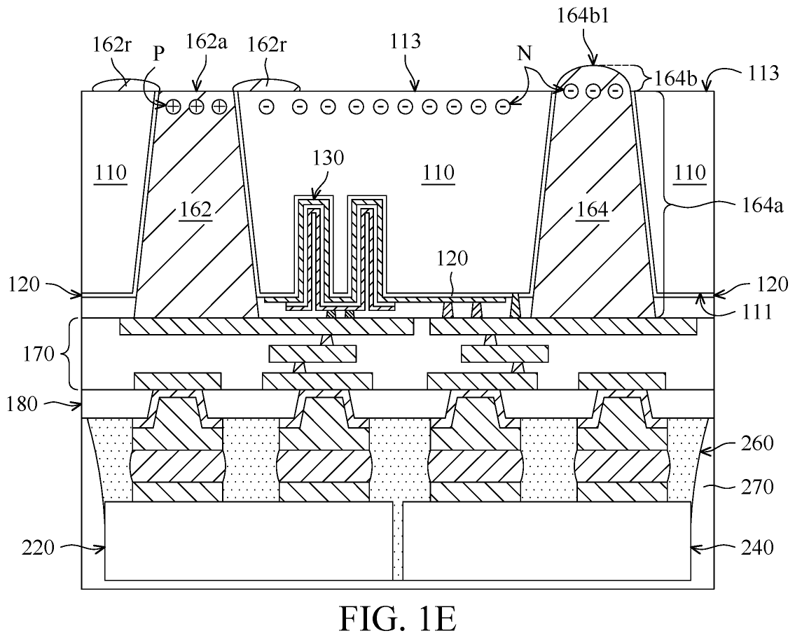

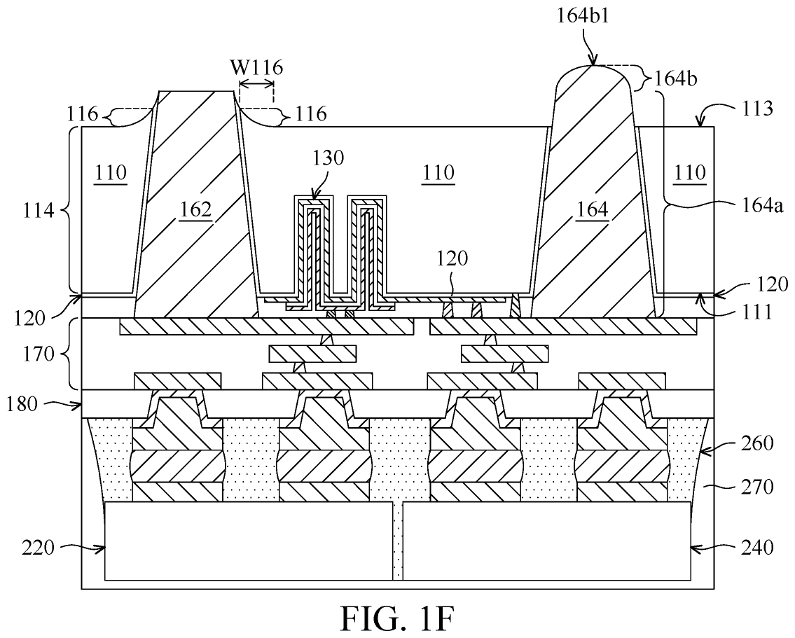

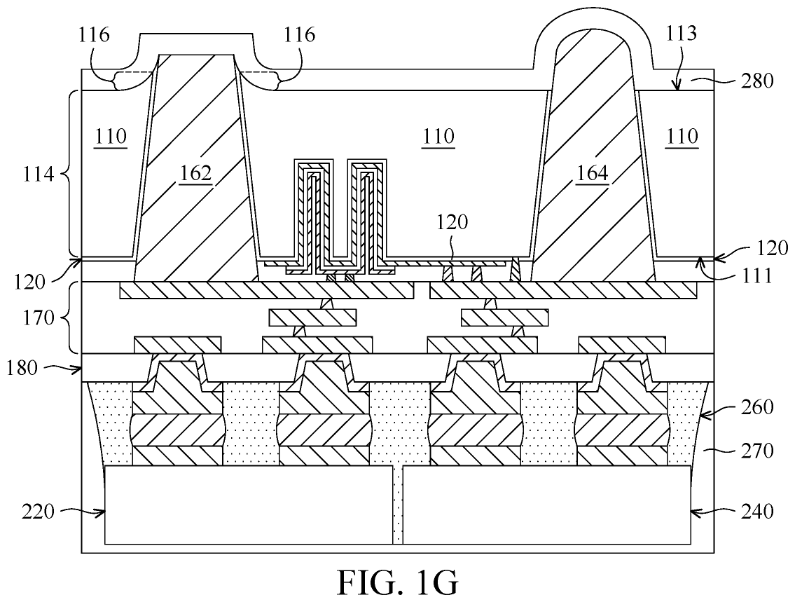

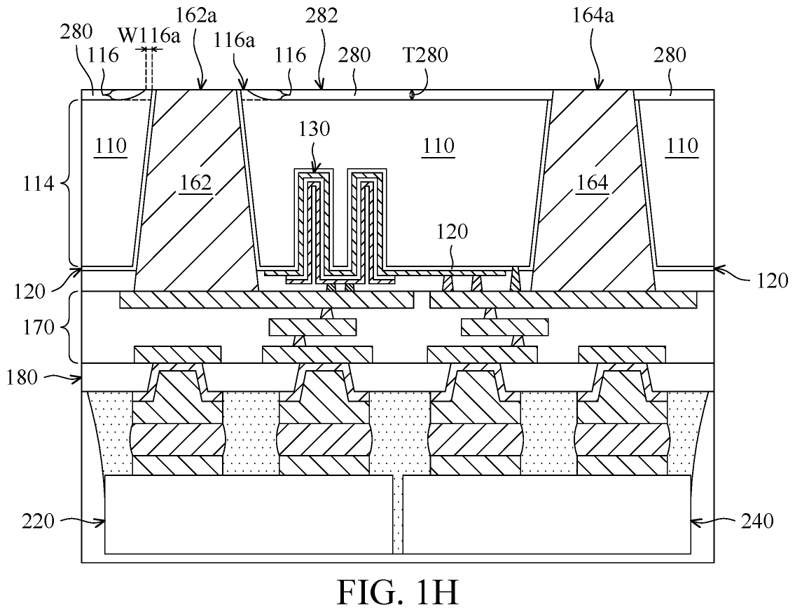

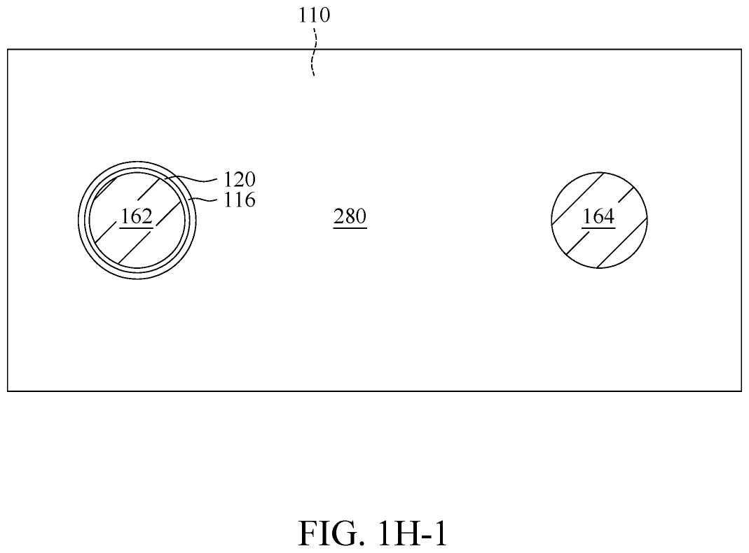

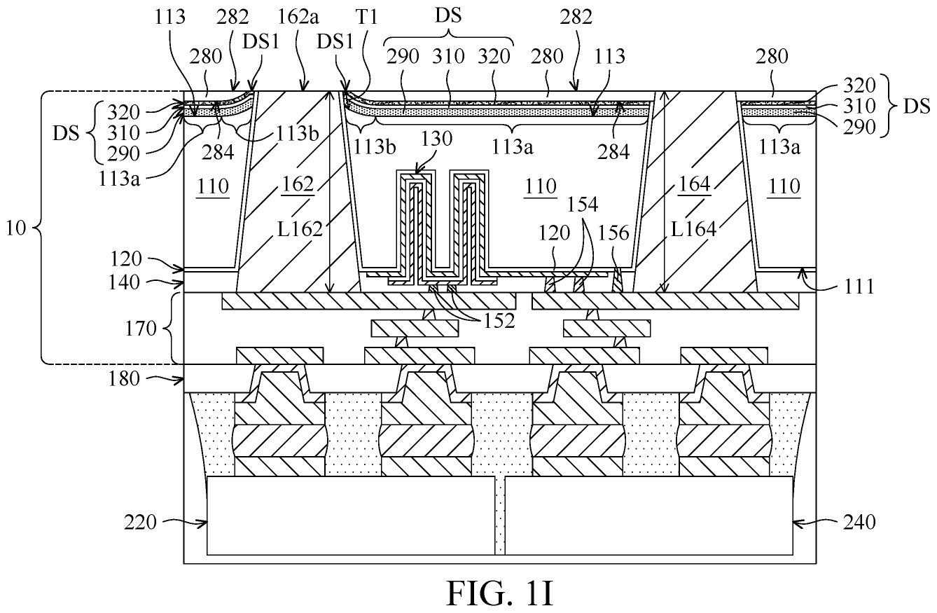

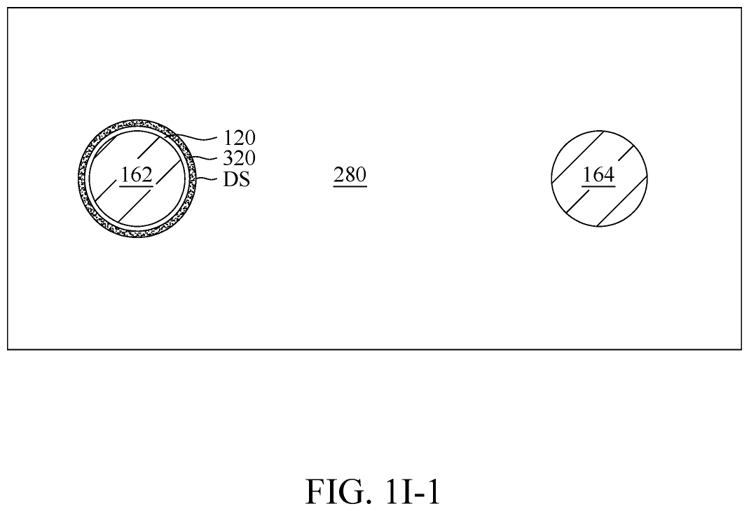

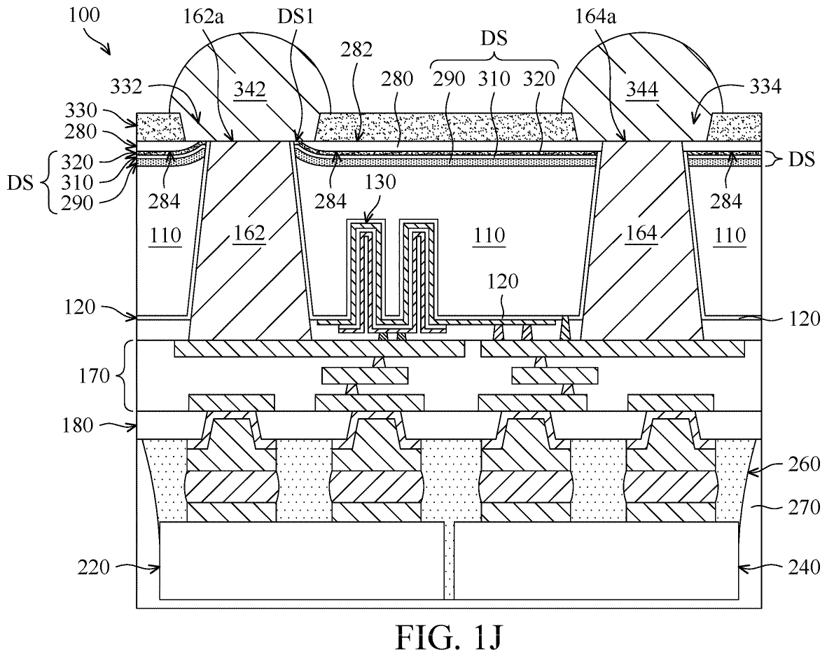

FIGS. 1A-1J are cross-sectional views of various stages of a process for forming a chip package structure, in accordance with some embodiments. As shown in FIG. 1A, a semiconductor substrate 110 is provided, in accordance with some embodiments.

The semiconductor substrate 110 has a front surface 111 and a back surface 113, in accordance with some embodiments. The back surface 113 is opposite to the front surface 111, in accordance with some embodiments. The semiconductor substrate 110 includes, for example, a semiconductor wafer (such as a silicon wafer) or a portion of a semiconductor wafer.

In some embodiments, the semiconductor substrate 110 is made of an elementary semiconductor material including silicon or germanium in a single crystal structure, a polycrystal structure, or an amorphous structure. In some other embodiments, the semiconductor substrate 110 is made of a compound semiconductor, such as silicon carbide, gallium arsenide, gallium phosphide, indium phosphide, indium arsenide, an alloy semiconductor, such as SiGe or GaAsP, or a combination thereof. The semiconductor substrate 110 may also include multi-layer semiconductors, semiconductor on insulator (SOI) (such as silicon on insulator or germanium on insulator), or a combination thereof.

In some embodiments, the semiconductor substrate 110 is a device wafer that includes various device elements. In some embodiments, the various device elements are formed in and/or over the semiconductor substrate 110. The device elements are not shown in figures for the purpose of simplicity and clarity.

Examples of the various device elements include active devices, passive devices, other suitable elements, or a combination thereof. The active devices may include transistors or diodes (not shown) formed at a surface of the semiconductor substrate 110. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc.

Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the semiconductor substrate 110. The isolation features are used to surround active regions and electrically isolate various device elements formed in and/or over the semiconductor substrate 110 in the active regions. In some embodiments, the isolation features include shallow trench isolation (STI) features, local oxidation of silicon (LOCOS) features, other suitable isolation features, or a combination thereof.

As shown in FIG. 1A, portions of the semiconductor substrate 110 are removed to form trenches 112 and holes 117 and 118, in accordance with some embodiments. The removal process includes an etching process such as a dry etching process, in accordance with some embodiments.

As shown in FIG. 1A, a dielectric layer 120 is formed over the front surface 111 of the semiconductor substrate 110 and in the trenches 112 and the holes 117 and 118, in accordance with some embodiments. The dielectric layer 120 is made of a dielectric material such as silicon oxide or silicon nitride, in accordance with some embodiments.

In some other embodiments, the dielectric layer 120 is made of a low-k material or a porous dielectric material having a k-value which is lower than that of silicon oxide, or lower than about 3.0 or about 2.5, in accordance with some embodiments.

The low-k material includes a fluorinated material, such as amorphous fluorinated carbon (α-C: F), poly-tetra-fluoro-ethylene (PTFE), fluorinated polyimide, or phosphor-silicate glass, in accordance with some embodiments.

Alternatively, the dielectric layer 120 includes an oxide-containing material (e.g., tetraethyl orthosilicate oxide), an oxynitride-containing material (e.g., silicon oxynitride), a glass material (e.g., borosilicate glass, phosphoric silicate glass, boron phospho-silicate glass, or fluorinated silicate glass), or a combination thereof, in accordance with some embodiments.

The dielectric layer 120 is formed using a thermal oxidation process, a chemical vapor deposition (CVD) process, such as a low-pressure CVD process, a plasma-enhanced CVD process, or a high-density plasma CVD process, an atomic layer deposition process, a spin-on process, a physical vapor deposition process, or another suitable process, in accordance with some embodiments.

As shown in FIG. 1A, a capacitor 130 is formed over the dielectric layer 120 and in the trenches 112, in accordance with some embodiments. The capacitor 130 is also referred to as an embedded-deep trench capacitor (DTC), in accordance with some embodiments.

The capacitor 130 includes a bottom electrode 132, an dielectric layer 134, and a top electrode 136, in accordance with some embodiments. The bottom electrode 132, the dielectric layer 134, and the top electrode 136 are sequentially stacked over the dielectric layer 120, in accordance with some embodiments.

The dielectric layer 134 electrically insulates the bottom electrode 132 from the top electrode 136, in accordance with some embodiments. The bottom electrode 132 is wider than the top electrode 136, in accordance with some embodiments. The bottom electrode 132 is wider than the dielectric layer 134, in accordance with some embodiments. The portions of the bottom electrode 132 are exposed by the top electrode 136, in accordance with some embodiments.

The bottom electrode 132 is made of a conductive material, such as metal (e.g., copper, aluminum, gold, silver, or tungsten) or alloys thereof, in accordance with some embodiments. The bottom electrode 132 is formed using a plating process, such as an electroplating process, in accordance with some embodiments.

The dielectric layer 134 is made of a dielectric material such as silicon oxide or silicon nitride, in accordance with some embodiments. The dielectric layer 134 is made of a low-k material or a porous dielectric material having a k-value which is lower than that of silicon oxide, or lower than about 3.0 or about 2.5, in accordance with some embodiments.

The low-k material includes a fluorinated material, such as amorphous fluorinated carbon (α-C: F), poly-tetra-fluoro-ethylene (PTFE), fluorinated polyimide, or phosphor-silicate glass, in accordance with some embodiments.

Alternatively, the dielectric layer 134 includes an oxide-containing material (e.g., silicon oxide or tetraethyl orthosilicate oxide), an oxynitride-containing material (e.g., silicon oxynitride), a glass material (e.g., borosilicate glass, phosphoric silicate glass, boron phospho-silicate glass, or fluorinated silicate glass), or a combination thereof, in accordance with some embodiments.

The dielectric layer 134 is formed using a chemical vapor deposition (CVD) process, such as a low-pressure CVD process, a plasma-enhanced CVD process, or a high-density plasma CVD process, an atomic layer deposition process, a spin-on process, a physical vapor deposition process, or another suitable process, in accordance with some embodiments.

The top electrode 136 is made of a conductive material, such as metal (e.g., copper, aluminum, gold, silver, or tungsten) or alloys thereof, in accordance with some embodiments. The top electrode 136 is formed using a plating process, such as an electroplating process, in accordance with some embodiments.

As shown in FIG. 1B, a dielectric layer 140 is formed over the dielectric layer 120 and the capacitor 130, in accordance with some embodiments. The dielectric layer 140 is made of a dielectric material such as silicon oxide or silicon nitride, in accordance with some embodiments.

The dielectric layer 140 is made of a low-k material or a porous dielectric material having a k-value which is lower than that of silicon oxide, or lower than about 3.0 or about 2.5, in accordance with some embodiments. The low-k material includes a fluorinated material, such as amorphous fluorinated carbon (α-C: F), poly-tetra-fluoro-ethylene (PTFE), fluorinated polyimide, or phosphor-silicate glass, in accordance with some embodiments.

Alternatively, the dielectric layer 140 includes an oxide-containing material (e.g., silicon oxide or tetraethyl orthosilicate oxide), an oxynitride-containing material (e.g., silicon oxynitride), a glass material (e.g., borosilicate glass, phosphoric silicate glass, boron phospho-silicate glass, or fluorinated silicate glass), or a combination thereof, in accordance with some embodiments.

The dielectric layer 140 is formed using a chemical vapor deposition (CVD) process, such as a low-pressure CVD process, a plasma-enhanced CVD process, or a high-density plasma CVD process, an atomic layer deposition process, a spin-on process, a physical vapor deposition process, or another suitable process, in accordance with some embodiments.

As shown in FIG. 1B, portions of the dielectric layers 120 and 140 are removed to form holes 142, 144, 146, 148 and 149 passing through the dielectric layer 140, in accordance with some embodiments. The holes 142 expose the top electrode 136, in accordance with some embodiments. The holes 144 expose the bottom electrode 132, in accordance with some embodiments.

The holes 146 pass through the dielectric layer 120 and expose the front surface 111 of the semiconductor substrate 110, in accordance with some embodiments. The holes 148 expose the dielectric layer 120 in the hole 117 of the semiconductor substrate 110, in accordance with some embodiments.

The holes 149 expose the dielectric layer 120 in the hole 118 of the semiconductor substrate 110, in accordance with some embodiments. The removal process includes an etching process such as a dry etching process, in accordance with some embodiments.

As shown in FIG. 1B, conductive vias 152, 154, 156, 162, and 164 are formed in the holes 142, 144, 146, 148, and 149 respectively, in accordance with some embodiments. The conductive via 162 is formed in the hole 117 of the semiconductor substrate 110, in accordance with some embodiments. The conductive via 164 is formed in the hole 118 of the semiconductor substrate 110, in accordance with some embodiments.

As shown in FIG. 1B, the dielectric layer 120 is between the semiconductor substrate 110 and the conductive via structure 162, in accordance with some embodiments. The dielectric layer 120 separates the semiconductor substrate 110 from the conductive via structure 162, in accordance with some embodiments.

The conductive vias 152, 154, 156, 162, and 164 are made of a conductive material, such as metal (e.g., copper, aluminum, gold, silver, or tungsten) or alloys thereof, in accordance with some embodiments. The conductive vias 152, 154, 156, 162, and 164 are formed using a deposition process (e.g., a physical vapor deposition process) and a planarization process (e.g., a chemical mechanical polishing process), in accordance with some embodiments.

As shown in FIG. 1C, a redistribution layer 170 is formed over the conductive vias 152, 154, 156, 162, and 164 and the dielectric layer 140, in accordance with some embodiments. The redistribution layer 170 includes a dielectric layer 172, wiring layers 174, conductive vias 176, and conductive pads 178, in accordance with some embodiments.

The wiring layers 174, the conductive vias 176, and the conductive pads 178 are in the dielectric layer 172, in accordance with some embodiments. The conductive vias 176 are electrically connected between the wiring layers 174 and the conductive pads 178, in accordance with some embodiments.

The conductive via structure 162 is electrically connected to the top electrode 136 of the capacitor 130 through the conductive vias 152 and the wiring layer 174, in accordance with some embodiments. The conductive via structure 164 is electrically connected to the bottom electrode 132 of the capacitor 130 through the conductive vias 154 and the wiring layer 174, in accordance with some embodiments.

The conductive via structure 164 and the bottom electrode 132 are electrically connected to the semiconductor substrate 110 through the conductive via 156, in accordance with some embodiments. The conductive via 156 is also referred to as a grounding via, in accordance with some embodiments.

The dielectric layer 172 is made of a dielectric material such as silicon oxide or silicon nitride, in accordance with some embodiments. The dielectric layer 172 is made of an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

Alternatively, the dielectric layer 172 includes a low-k material or a porous dielectric material having a k-value which is lower than that of silicon oxide, or lower than about 3.0 or about 2.5, in accordance with some embodiments. The wiring layers 174 are made of a conductive material, such as metal (e.g., copper, aluminum, gold, silver, tin, or tungsten) or alloys thereof, in accordance with some embodiments.

The conductive vias 176 are made of a conductive material, such as metal (e.g., copper, aluminum, gold, silver, tin, or tungsten) or alloys thereof, in accordance with some embodiments. The conductive pads 178 are made of a conductive material, such as metal (e.g., copper, aluminum, gold, silver, tin, or tungsten) or alloys thereof, in accordance with some embodiments.

As shown in FIG. 1C, a passivation layer 180 is formed over the redistribution layer 170, in accordance with some embodiments. The passivation layer 180 has openings 182, in accordance with some embodiments. The openings 182 expose the conductive pads 178 respectively, in accordance with some embodiments. The passivation layer 180 is made of a dielectric material such as an oxynitride-containing material (e.g., silicon oxynitride), in accordance with some embodiments.

The passivation layer 180 is formed using a deposition process and an etching process, in accordance with some embodiments. The deposition process includes a chemical vapor deposition (CVD) process, such as a low-pressure CVD process, a plasma-enhanced CVD process, or a high-density plasma CVD process, an atomic layer deposition process, a spin-on process, a physical vapor deposition process, or another suitable process, in accordance with some embodiments.

As shown in FIG. 1C, conductive layers 190 and conductive bumps 210 are sequentially formed over the conductive pads 178, in accordance with some embodiments. Each conductive layer 190 conformally covers the corresponding conductive pad 178 and the passivation layer 180, in accordance with some embodiments. Each conductive bump 210 is formed over the corresponding conductive layer 190, in accordance with some embodiments.

The conductive layers 190 are made of a conductive material, such as metal (e.g., nickel, palladium, gold, copper, aluminum, silver, tin, or tungsten) or alloys thereof, in accordance with some embodiments. The conductive layers 190 are referred to as under bump metallurgy (UBM) layers, in accordance with some embodiments. The conductive layers 190 are formed using a plating process, such as an electroplating process, in accordance with some embodiments.

The conductive bumps 210 are made of a conductive material, such as metal (e.g., gold, copper, aluminum, silver, tin, or tungsten) or alloys thereof, in accordance with some embodiments. The conductive bumps 210 are formed using a plating process, such as an electroplating process, in accordance with some embodiments.

As shown in FIG. 1D, a chip 220 is bonded to the conductive bumps 210 through solder bumps 230, and a chip 240 is bonded to the conductive bumps 210 through solder bumps 250, in accordance with some embodiments.

The chip 220 has a substrate 222 and conductive pillars 224, in accordance with some embodiments. The conductive pillars 224 are over the substrate 222, in accordance with some embodiments. The substrate 222 includes, for example, a semiconductor substrate. In some embodiments, the substrate 222 is made of an elementary semiconductor material including silicon or germanium in a single crystal structure, a polycrystal structure, or an amorphous structure.

In some other embodiments, the substrate 222 is made of a compound semiconductor, such as silicon carbide, gallium arsenide, gallium phosphide, indium phosphide, indium arsenide, an alloy semiconductor, such as SiGe or GaAsP, or a combination thereof. The substrate 222 may also include multi-layer semiconductors, semiconductor on insulator (SOI) (such as silicon on insulator or germanium on insulator), or a combination thereof.

In some embodiments, the substrate 222 is a device substrate that includes various device elements. In some embodiments, the various device elements are formed in and/or over the substrate 222. The device elements are not shown in figures for the purpose of simplicity and clarity.

Examples of the various device elements include active devices, passive devices, other suitable elements, or a combination thereof. The active devices may include transistors or diodes (not shown) formed at a surface of the substrate 222. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc.

Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the substrate 222. The isolation features are used to surround active regions and electrically isolate various device elements formed in and/or over the substrate 222 in the active regions. In some embodiments, the isolation features include shallow trench isolation (STI) features, local oxidation of silicon (LOCOS) features, other suitable isolation features, or a combination thereof.

The conductive pillars 224 are electrically connected to the device elements formed in and/or over the substrate 222 in the active regions, in accordance with some embodiments. The conductive pillars 224 are made of a conductive material, such as metal (e.g., copper, aluminum, gold, silver, tin, or tungsten) or alloys thereof, in accordance with some embodiments. The solder bumps 230 are made of a conductive material, such as a tin-based alloy, in accordance with some embodiments.

The chip 240 has a substrate 242 and conductive pillars 244, in accordance with some embodiments. The conductive pillars 244 are over the substrate 242, in accordance with some embodiments. The substrate 242 includes, for example, a semiconductor substrate. In some embodiments, the substrate 242 is made of an elementary semiconductor material including silicon or germanium in a single crystal structure, a polycrystal structure, or an amorphous structure.

In some other embodiments, the substrate 242 is made of a compound semiconductor, such as silicon carbide, gallium arsenide, gallium phosphide, indium phosphide, indium arsenide, an alloy semiconductor, such as SiGe or GaAsP, or a combination thereof. The substrate 242 may also include multi-layer semiconductors, semiconductor on insulator (SOI) (such as silicon on insulator or germanium on insulator), or a combination thereof.

In some embodiments, the substrate 242 is a device substrate that includes various device elements. In some embodiments, the various device elements are formed in and/or over the substrate 242. The device elements are not shown in figures for the purpose of simplicity and clarity.

Examples of the various device elements include active devices, passive devices, other suitable elements, or a combination thereof. The active devices may include transistors or diodes (not shown) formed at a surface of the substrate 242. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc.

Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the substrate 242. The isolation features are used to surround active regions and electrically isolate various device elements formed in and/or over the substrate 242 in the active regions. In some embodiments, the isolation features include shallow trench isolation (STI) features, local oxidation of silicon (LOCOS) features, other suitable isolation features, or a combination thereof.

The conductive pillars 244 are electrically connected to the device elements formed in and/or over the substrate 242 in the active regions, in accordance with some embodiments. The conductive pillars 244 are made of a conductive material, such as metal (e.g., copper, aluminum, gold, silver, tin, or tungsten) or alloys thereof, in accordance with some embodiments. The solder bumps 250 are made of a conductive material, such as a tin-based alloy, in accordance with some embodiments.

As shown in FIG. 1D, an underfill layer 260 is formed between the chips 220 and 240 and the passivation layer 180, in accordance with some embodiments. The underfill layer 260 surrounds the chips 220 and 240, the solder bumps 230 and 250, the conductive bumps 210, and the conductive layers 190, in accordance with some embodiments. The underfill layer 260 is made of an insulating material such as a polymer material, in accordance with some embodiments.

As shown in FIG. 1D, a molding layer 270 is formed over the chips 220 and 240 and the underfill layer 260, in accordance with some embodiments. The molding layer 270 surrounds the chips 220 and 240 and the underfill layer 260, in accordance with some embodiments. The molding layer 270 is made of an insulating material such as a polymer material, in accordance with some embodiments.

In some embodiments, an electrical test is performed, in accordance with some embodiments. In some embodiments, a first test voltage applied to the conductive via structure 162 is higher than a second test voltage applied to the conductive via structure 164. Therefore, some positive charges P are formed at the conductive via structure 162, and some negative charges N are formed at the conductive via structure 164 and the semiconductor substrate 110, in accordance with some embodiments.

Since the conductive via structures 162 and 164 are electrically connected to the capacitor 130, the positive charges P and the negative charges N are remained after the electrical test, in accordance with some embodiments.

As shown in FIG. 1E, the semiconductor substrate 110 is flipped upside down, in accordance with some embodiments. As shown in FIG. 1E, portions of the semiconductor substrate 110, the dielectric layer 120, and the conductive via structures 162 and 164 are removed to expose the conductive via structures 162 and 164, in accordance with some embodiments.

The conductive via structures 162 and 164 pass through the semiconductor substrate 110, in accordance with some embodiments. The conductive via structure 164 is longer than the conductive via structure 162, in accordance with some embodiments. The removal process includes a planarization process such as a chemical mechanical polishing process, in accordance with some embodiments.

During the removal process, since the positive charges P remain at the conductive via structure 162, the removed portions of the conductive via structure 162 can dissociate into positively charged metal ions, and the positively charged metal ions are adsorbed to the back surface 113 (i.e., a negative-charge surface) of the semiconductor substrate 110, thereby forms a conductive residue 162r over the back surface 113 adjacent to the conductive via structure 162.

Since the negative charges N also remain at the conductive via structure 164 after the electrical test, the positively charged metal ions are also adsorbed to the conductive via structure 164, in accordance with some embodiments. Therefore, the conductive via structure 164 has a protruding portion 164b protruding from the back surface 113, in accordance with some embodiments.

The protruding portion 164b is formed from the positively charged metal ions, in accordance with some embodiments. The conductive via structure 164 has a main portion 164a and the protruding portion 164b over the main portion 164a, in accordance with some embodiments. The main portion 164a passes through the semiconductor substrate 110, in accordance with some embodiments.

The protruding portion 164b has a convex surface 164b1, in accordance with some embodiments. The convex surface 164b1 faces away from the front surface 111, in accordance with some embodiments. The convex surface 164b1 is a convex curved surface, in accordance with some embodiments. The convex surface 164b1 is higher than the end surface 162a of the conductive via structure 162, in accordance with some embodiments.

As shown in FIG. 1F, the conductive residue 162r and portions of the semiconductor substrate 110 are removed from the back surface 113 of the semiconductor substrate 110, in accordance with some embodiments. Since the conductive residue 162r hinders etching of the portions of the semiconductor substrate 110 thereunder, the semiconductor substrate 110 has a protruding portion 116 after the removal process, in accordance with some embodiments.

The semiconductor substrate 110 has a base portion 114 and the protruding portion 116 over the base portion 114, in accordance with some embodiments. The protruding portion 116 surrounds the conductive via structure 162, in accordance with some embodiments.

A width of the protruding portion 116 of the semiconductor substrate 110 increases toward the base portion 114 of the semiconductor substrate 110, in accordance with some embodiments. The maximum width W116 of the protruding portion 116 ranges from about 0.1 μm to about 5 μm, in accordance with some embodiments. The removal process includes an etching process such as a dry etching process or a wet etching process, in accordance with some embodiments.

As shown in FIG. 1G, an insulating layer 280 is formed over the back surface 113 of the semiconductor substrate 110 and the conductive via structures 162 and 164, in accordance with some embodiments. The insulating layer 280 is made of a dielectric material such as silicon oxide or silicon nitride, in accordance with some embodiments.

In some other embodiments, the dielectric material includes an oxynitride-containing material (e.g., silicon oxynitride), a carbon-containing material (e.g., silicon carbide or silicon oxycarbide), a fluorine-containing material (e.g., silicon fluoride or silicon oxyfluoride), a chloride-containing material (e.g., silicon chloride or silicon oxychloride), or a combination thereof, in accordance with some embodiments.

The insulating layer 280 is formed using a chemical vapor deposition (CVD) process, such as a low-pressure CVD process, a plasma-enhanced CVD process, or a high-density plasma CVD process, an atomic layer deposition process, a spin-on process, a physical vapor deposition process, or another suitable process, in accordance with some embodiments.

FIG. 1H-1 is a top view of the semiconductor device structure of FIG. 1H, in accordance with some embodiments. As shown in FIGS. 1H and 1H-1, top parts of the conductive via structures 162 and 164, the dielectric layer 120, the protruding portion 116 of the semiconductor substrate 110, and the insulating layer 280 are removed, in accordance with some embodiments. The removal process includes a planarization process such as a chemical mechanical polishing process, in accordance with some embodiments.

In some embodiments, an end surface 162a of the conductive via structure 162, an end surface 116a of the protruding portion 116, and a surface 282 of the insulating layer 280 are substantially level with each other. The thickness T280 of the insulating layer 280 ranges from about 0.5 μm to about 1.5 μm, in accordance with some embodiments.

The protruding portion 116 has a trapezoid shape, in accordance with some embodiments. In some embodiments, a minimum width W116a of the protruding portion 116 ranges from about 0.1 μm to about 5 μm, in accordance with some embodiments. As shown in FIG. 1H-1, the protruding portion 116 surrounds the conductive via structure 162, in accordance with some embodiments.

FIG. 1I-1 is a top view of the semiconductor device structure of FIG. 1I, in accordance with some embodiments. As shown in FIGS. 1H, 1I, and 1I-1, the protruding portion 116 and a top part of the base portion 114 are converted into a dielectric structure DS, in accordance with some embodiments.

The dielectric structure DS is between the insulating layer 280 and the semiconductor substrate 110, in accordance with some embodiments. The dielectric structure DS surrounds the conductive via structure 162, in accordance with some embodiments.

The dielectric structure DS has a higher dielectric constant than the protruding portion 116, in accordance with some embodiments. The dielectric structure DS has a higher dielectric constant than the semiconductor substrate 110, in accordance with some embodiments.

The dielectric structure DS electrically insulates the semiconductor substrate 110 from a conductive bump formed over the conductive via 162 in the subsequent process, in accordance with some embodiments. The dielectric structure DS is thicker than the insulating layer 280, in accordance with some embodiments. The thickness T1 of the dielectric structure DS ranges from about 1 μm to about 5 μm, in accordance with some embodiments.

The back surface 113 has a flat portion 113a and a sloped portion 113b, in accordance with some embodiments. The sloped portion 113b is between the conductive via structure 162 and the flat portion 113a, in accordance with some embodiments.

The dielectric structure DS is over the sloped portion 113b and the flat portion 113a, in accordance with some embodiments. The dielectric structure DS is wider than the conductive via structure 162, in accordance with some embodiments. The dielectric structure DS has an L-like shape, in accordance with some embodiments.

The end surface 162a of the conductive via structure 162, an end surface DS1 of the dielectric structure DS, and the surface 282 of the insulating layer 280 are substantially level with each other, in accordance with some embodiments. The dielectric layer 120 separates the conductive via structure 162 from the dielectric structure DS, in accordance with some embodiments.

The dielectric structure DS includes dielectric layers 290, 310, and 320, in accordance with some embodiments. The dielectric layer 290 is between the semiconductor substrate 110 and the dielectric layer 310, in accordance with some embodiments.

The dielectric layer 310 is between the dielectric layers 290 and 320, in accordance with some embodiments. The dielectric layer 320 is between the dielectric layer 310 and the insulating layer 280, in accordance with some embodiments.

The dielectric layer 320 conformally covers a surface 284 of the insulating layer 280, in accordance with some embodiments. The dielectric layer 320 has a higher dielectric constant than the dielectric layer 310, in accordance with some embodiments. The dielectric layer 310 has a higher dielectric constant than the dielectric layer 290, in accordance with some embodiments.

The dielectric layer 320 is thinner than the dielectric layer 310, in accordance with some embodiments. The dielectric layer 310 is thinner than the dielectric layer 290, in accordance with some embodiments. Therefore, the dielectric constant of the dielectric structure DS is lower than the dielectric constant of the dielectric layer 320, thereby reducing the parasitic capacitance generated by the dielectric structure DS and improving the electrical insulation performance of the dielectric structure DS, in accordance with some embodiments.

The semiconductor substrate 110, the dielectric layer 120, the capacitor 130, the dielectric layer 140, the conductive vias 152, 154, 156, 162, and 164, the redistribution layer 170, the insulating layer 280, and the dielectric structure DS together form an interposer structure 10, in accordance with some embodiments.

The dielectric layer 290 is made of a dielectric material such as silicon oxide or silicon nitride, in accordance with some embodiments. In some other embodiments, the dielectric material includes an oxynitride-containing material (e.g., silicon oxynitride), a carbon-containing material (e.g., silicon carbide or silicon oxycarbide), a fluorine-containing material (e.g., silicon fluoride or silicon oxyfluoride), a chloride-containing material (e.g., silicon chloride or silicon oxychloride), or a combination thereof, in accordance with some embodiments.

In some embodiments, the dielectric layer 290 and the insulating layer 280 are made of the same material. In some other embodiments, the dielectric layer 290 and the insulating layer 280 are made of different materials.

The dielectric layer 310 is made of a dielectric material such as silicon oxide or silicon nitride, in accordance with some embodiments. In some other embodiments, the dielectric material includes an oxynitride-containing material (e.g., silicon oxynitride), a carbon-containing material (e.g., silicon carbide or silicon oxycarbide), a fluorine-containing material (e.g., silicon fluoride or silicon oxyfluoride), a chloride-containing material (e.g., silicon chloride or silicon oxychloride), or a combination thereof, in accordance with some embodiments.

In some embodiments, the dielectric layer 310 and the insulating layer 280 are made of the same material. In some other embodiments, the dielectric layer 310 and the insulating layer 280 are made of different materials.

The dielectric layer 320 is made of a dielectric material such as silicon oxide or silicon nitride, in accordance with some embodiments. In some other embodiments, the dielectric material includes an oxynitride-containing material (e.g., silicon oxynitride), a carbon-containing material (e.g., silicon carbide or silicon oxycarbide), a fluorine-containing material (e.g., silicon fluoride or silicon oxyfluoride), a chloride-containing material (e.g., silicon chloride or silicon oxychloride), or a combination thereof, in accordance with some embodiments.

In some embodiments, the dielectric layer 320 and the insulating layer 280 are made of the same material. In some other embodiments, the dielectric layer 320 and the insulating layer 280 are made of different materials.

The dielectric structure DS is formed using thermal diffusion processes, in accordance with some embodiments. The formation of the dielectric structure DS includes performing a first thermal diffusion process to form the dielectric layer 290; performing a second thermal diffusion process to form the dielectric layer 310; and performing a third thermal diffusion process to form the dielectric layer 320, in accordance with some embodiments.

The average width of the conductive via structure 162 ranges from about 15 μm to about 25 μm, in accordance with some embodiments. The average width of the conductive via structure 164 ranges from about 15 μm to about 25 μm, in accordance with some embodiments.

The length L162 of the conductive via structure 162 ranges from about 30 μm to about 110 μm, in accordance with some embodiments. The length L164 of the conductive via structure 164 ranges from about 30 μm to about 110 μm, in accordance with some embodiments.

As shown in FIG. 1J, a passivation layer 330 is formed over the insulating layer 280, in accordance with some embodiments. The passivation layer 330 has openings 332 and 334, in accordance with some embodiments. The opening 332 exposes the end surface 162a of the conductive via structure 162, the end surface DS1 of the dielectric structure DS, and a portion of the surface 282 of the insulating layer 280, in accordance with some embodiments.

The opening 334 exposes the end surface 164a of the conductive via structure 164 and a portion of the surface 282 of the insulating layer 280, in accordance with some embodiments. The passivation layer 330 is made of an insulating material such as a polymer material, in accordance with some embodiments.

As shown in FIG. 1J, conductive bumps 342 and 344 are formed over the conductive via structures 162 and 164 respectively, in accordance with some embodiments. In this step, a chip package structure 100 is substantially formed, in accordance with some embodiments.

The conductive bump 342 is in the opening 332, in accordance with some embodiments. The conductive bump 344 is in the opening 334, in accordance with some embodiments. The conductive bumps 342 and 344 are electrically connected to the conductive via structures 162 and 164 respectively, in accordance with some embodiments. The conductive bump 342 is over the end surface DS1 of the dielectric structure DS, in accordance with some embodiments.

The dielectric structure DS electrically insulates the conductive bump 342 from the semiconductor substrate 110, thereby improving the yield of the chip package structure 100, in accordance with some embodiments.

The conductive bumps 342 and 344 are made of a conductive material, such as an alloy material (e.g., a solder material), in accordance with some embodiments. The solder material includes Tin (Sn), in accordance with some embodiments.

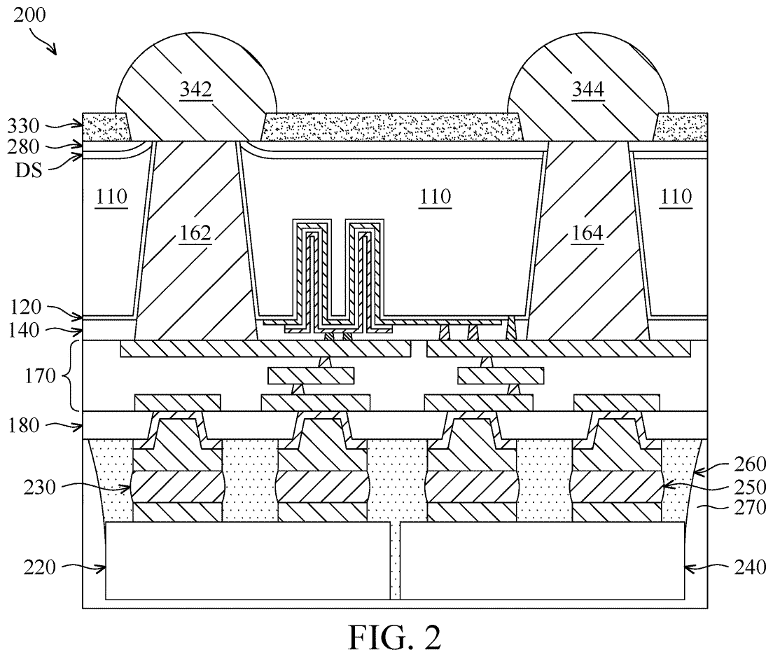

FIG. 2 is a cross-sectional view of a chip package structure 200, in accordance with some embodiments. As shown in FIG. 2, the chip package structure 200 is similar to the chip package structure 100 of FIG. 1J, except that the dielectric structure DS of the chip package structure 200 is a single-layered structure, in accordance with some embodiments.

The average width of the conductive via structure 162 ranges from about 5 μm to about 15 μm, in accordance with some embodiments. The average width of the conductive via structure 164 ranges from about 5 μm to about 15 μm, in accordance with some embodiments.

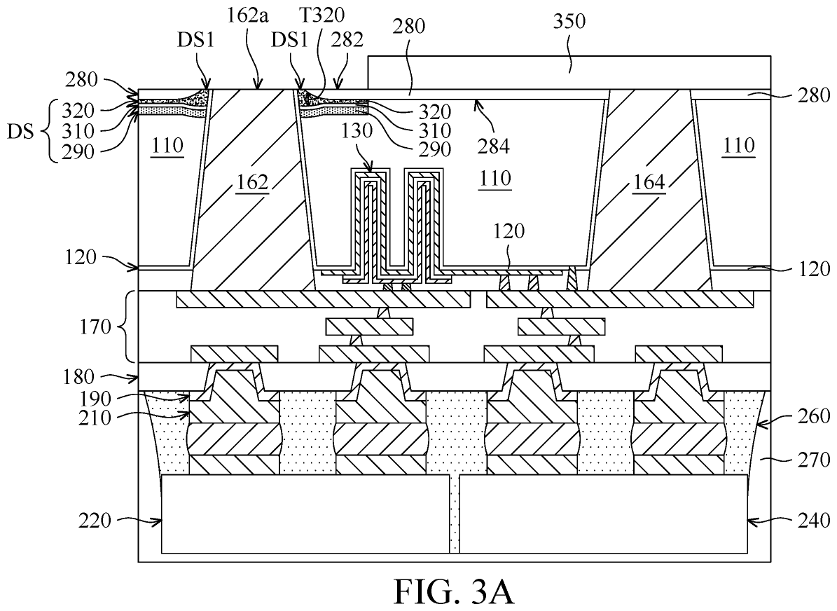

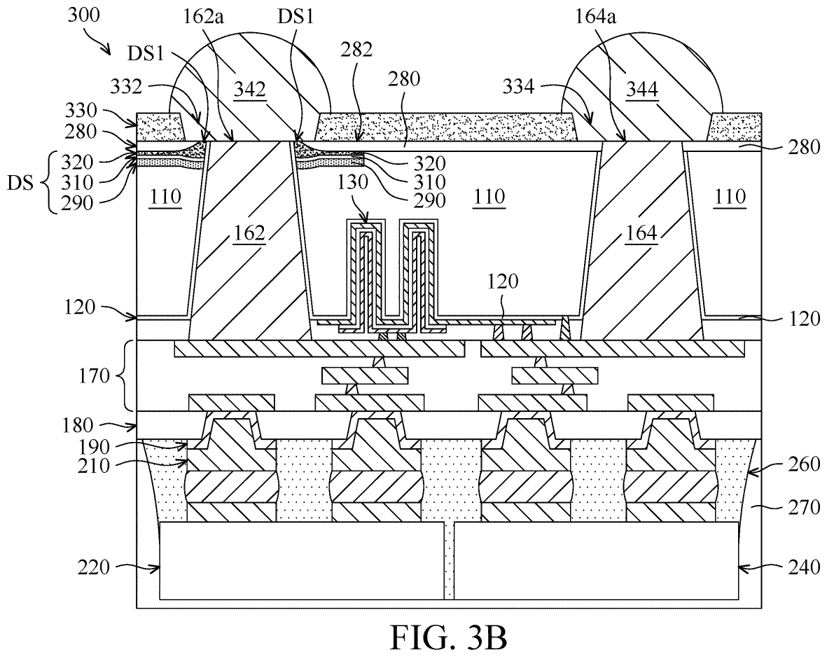

FIGS. 3A-3B are cross-sectional views of various stages of a process for forming a chip package structure, in accordance with some embodiments. As shown in FIG. 3A, after the step of FIG. 1H, a mask layer 350 is formed over the conductive via structure 164 and the insulating layer 280, in accordance with some embodiments.

As shown in FIGS. 1H and 3A, the protruding portion 116 and a top part of the base portion 114 are converted into a dielectric structure DS, in accordance with some embodiments. The dielectric structure DS is between the insulating layer 280 and the semiconductor substrate 110, in accordance with some embodiments.

The dielectric structure DS surrounds the conductive via structure 162, in accordance with some embodiments. The conductive via structure 162 is closer to the dielectric structure DS than the conductive via structure 164, in accordance with some embodiments. The dielectric structure DS has an L-like shape, in accordance with some embodiments.

The end surface 162a of the conductive via structure 162, an end surface DS1 of the dielectric structure DS, and the surface 282 of the insulating layer 280 are substantially level with each other, in accordance with some embodiments. The dielectric layer 120 separates the conductive via structure 162 from the dielectric structure DS, in accordance with some embodiments.

The dielectric structure DS includes dielectric layers 290, 310, and 320, in accordance with some embodiments. The dielectric layer 290 is between the semiconductor substrate 110 and the dielectric layer 310, in accordance with some embodiments. The dielectric layer 310 is between the dielectric layers 290 and 320, in accordance with some embodiments.

The dielectric layer 320 is between the dielectric layer 310 and the insulating layer 280, in accordance with some embodiments. The thickness T320 of the dielectric layer 320 continuously increases toward the conductive via structure 162, in accordance with some embodiments.

The dielectric layer 320 has a higher dielectric constant than the dielectric layer 310, in accordance with some embodiments. The dielectric layer 310 has a higher dielectric constant than the dielectric layer 290, in accordance with some embodiments. The dielectric layer 320 is thinner than the dielectric layer 310, in accordance with some embodiments. The dielectric layer 310 is thinner than the dielectric layer 290, in accordance with some embodiments.

Therefore, the dielectric constant of the dielectric structure DS is lower than the dielectric constant of the dielectric layer 320, thereby reducing the parasitic capacitance generated by the dielectric structure DS and improving the electrical insulation performance of the dielectric structure DS, in accordance with some embodiments.

The dielectric layer 290 is made of a dielectric material such as silicon oxide or silicon nitride, in accordance with some embodiments. In some other embodiments, the dielectric material includes an oxynitride-containing material (e.g., silicon oxynitride), a carbon-containing material (e.g., silicon carbide or silicon oxycarbide), a fluorine-containing material (e.g., silicon fluoride or silicon oxyfluoride), a chloride-containing material (e.g., silicon chloride or silicon oxychloride), or a combination thereof, in accordance with some embodiments.

In some embodiments, the dielectric layer 290 and the insulating layer 280 are made of the same material. In some other embodiments, the dielectric layer 290 and the insulating layer 280 are made of different materials.

The dielectric layer 310 is made of a dielectric material such as silicon oxide or silicon nitride, in accordance with some embodiments. In some other embodiments, the dielectric material includes an oxynitride-containing material (e.g., silicon oxynitride), a carbon-containing material (e.g., silicon carbide or silicon oxycarbide), a fluorine-containing material (e.g., silicon fluoride or silicon oxyfluoride), a chloride-containing material (e.g., silicon chloride or silicon oxychloride), or a combination thereof, in accordance with some embodiments.

In some embodiments, the dielectric layer 310 and the insulating layer 280 are made of the same material. In some other embodiments, the dielectric layer 310 and the insulating layer 280 are made of different materials.

The dielectric layer 320 is made of a dielectric material such as silicon oxide or silicon nitride, in accordance with some embodiments. In some other embodiments, the dielectric material includes an oxynitride-containing material (e.g., silicon oxynitride), a carbon-containing material (e.g., silicon carbide or silicon oxycarbide), a fluorine-containing material (e.g., silicon fluoride or silicon oxyfluoride), a chloride-containing material (e.g., silicon chloride or silicon oxychloride), or a combination thereof, in accordance with some embodiments.

In some embodiments, the dielectric layer 320 and the insulating layer 280 are made of the same material. In some other embodiments, the dielectric layer 320 and the insulating layer 280 are made of different materials.

The dielectric structure DS is formed using ion implantation processes, in accordance with some embodiments. The formation of the dielectric structure DS includes performing a first ion implantation process to form the dielectric layer 290; performing a second ion implantation process to form the dielectric layer 310; and performing a third ion implantation process to form the dielectric layer 320, in accordance with some embodiments.

The ion implantation processes are performed by using different implantation tilt angles and rotating the semiconductor substrate 110 to uniformly form the dielectric structure DS, thereby electrically insulating the semiconductor substrate 110 from a conductive bump formed over the conductive via 162 in the subsequent process, in accordance with some embodiments.

The ion implantation processes include a SIMOX-like process (i.e., separation by implantation of oxygen), in accordance with some embodiments. The dosage of the ion implantation processes ranges from about 1*10¹⁸ ions/cm² to about 1*10¹⁹ ions/cm², in accordance with some embodiments. The implant energy of the ion implantation processes ranges from about 100 keV to about 200 keV, in accordance with some embodiments.

The implant energy for forming the dielectric layer 290 is greater than the implant energy for forming the dielectric layer 310, in accordance with some embodiments. The implant energy for forming the dielectric layer 310 is greater than the implant energy for forming the dielectric layer 320, in accordance with some embodiments. The ions for forming the dielectric structure DS includes oxygen ions, nitrogen ions, fluorine ions, chlorine ions, or carbon ions, in accordance with some embodiments.

As shown in FIG. 3B, the mask layer 350 is removed, in accordance with some embodiments. As shown in FIG. 3B, a passivation layer 330 is formed over the insulating layer 280, in accordance with some embodiments. The passivation layer 330 has openings 332 and 334, in accordance with some embodiments.

The opening 332 exposes the end surface 162a of the conductive via structure 162, the end surface DS1 of the dielectric structure DS, and a portion of the surface 282 of the insulating layer 280, in accordance with some embodiments. The opening 334 exposes the end surface 164a of the conductive via structure 164 and a portion of the surface 282 of the insulating layer 280, in accordance with some embodiments.

As shown in FIG. 3B, conductive bumps 342 and 344 are formed over the conductive via structures 162 and 164 respectively, in accordance with some embodiments. In this step, a chip package structure 300 is substantially formed, in accordance with some embodiments.

The conductive bump 342 is in the opening 332, in accordance with some embodiments. The conductive bump 344 is in the opening 334, in accordance with some embodiments. The conductive bumps 342 and 344 are electrically connected to the conductive via structures 162 and 164 respectively, in accordance with some embodiments. The conductive bump 342 is over the end surface DS1 of the dielectric structure DS, in accordance with some embodiments.

The dielectric structure DS electrically insulates the conductive bump 342 from the semiconductor substrate 110, thereby improving the yield of the chip package structure 300, in accordance with some embodiments.

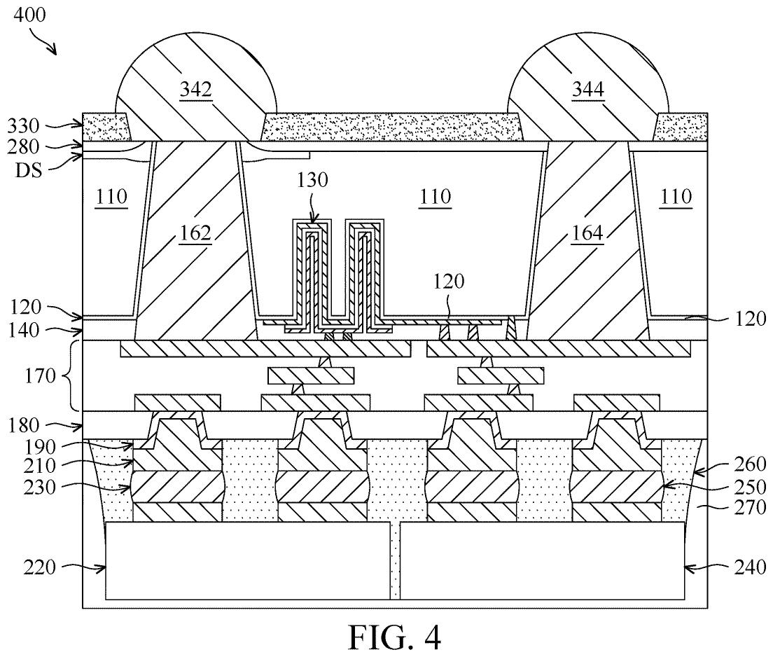

FIG. 4 is a cross-sectional view of a chip package structure 400, in accordance with some embodiments. As shown in FIG. 4, the chip package structure 400 is similar to the chip package structure 300 of FIG. 3B, except that the dielectric structure DS of the chip package structure 400 is a single-layered structure, in accordance with some embodiments.

The average width of the conductive via structure 162 ranges from about 5 μm to about 15 μm, in accordance with some embodiments. The average width of the conductive via structure 164 ranges from about 5 μm to about 15 μm, in accordance with some embodiments.

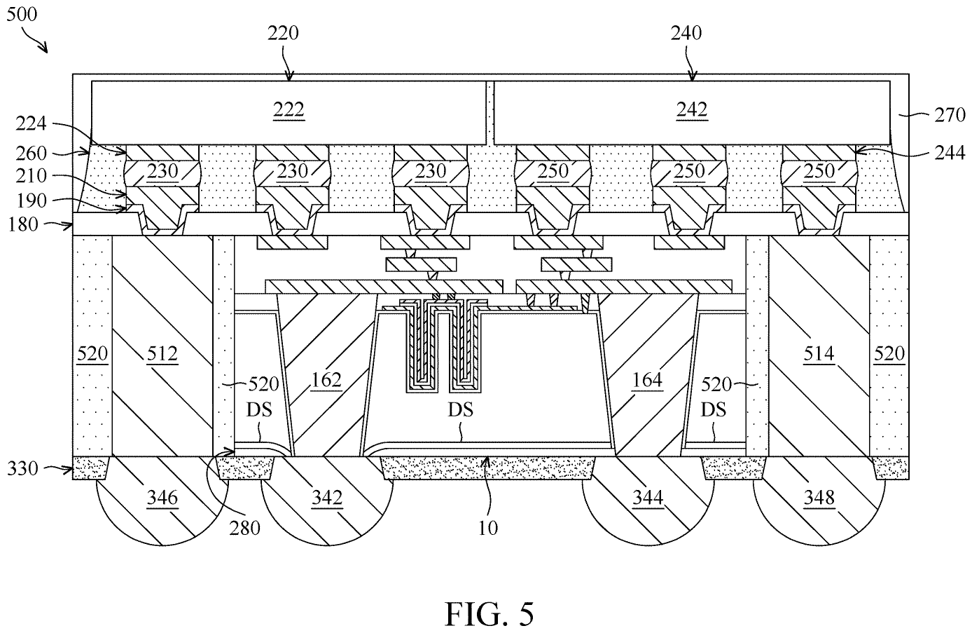

FIG. 5 is a cross-sectional view of a chip package structure 500, in accordance with some embodiments. As shown in FIG. 5, the chip package structure 500 is similar to the chip package structure 200 of FIG. 2, except that the chip package structure 500 further includes conductive plugs 512 and 514, a molding layer 520, and conductive bumps 346 and 348, in accordance with some embodiments.

The conductive plugs 512 and 514 are adjacent to the interposer structure 10, in accordance with some embodiments. The molding layer 520 surrounds the interposer structure 10 and the conductive plugs 512 and 514, in accordance with some embodiments.

The conductive bump 346 passes through the passivation layer 330 and is connected to the conductive plug 512, in accordance with some embodiments. The conductive bump 348 passes through the passivation layer 330 and is connected to the conductive plug 514, in accordance with some embodiments.

The conductive bump 346 is electrically connected to the chip 220 through the conductive plug 512, the corresponding conductive layer 190, the corresponding conductive bump 210, and the corresponding solder bump 230, in accordance with some embodiments.

The conductive bump 348 is electrically connected to the chip 240 through the conductive plug 514, the corresponding conductive layer 190, the corresponding conductive bump 210, and the corresponding solder bump 250, in accordance with some embodiments.

The conductive plugs 512 and 514 are made of a conductive material, such as metal (e.g., copper, aluminum, gold, silver, or tungsten) or alloys thereof, in accordance with some embodiments. The conductive plugs 512 and 514 are formed using a plating process, such as an electroplating process, in accordance with some embodiments.

The molding layer 520 is made of an insulating material such as a polymer material, in accordance with some embodiments. The conductive bumps 346 and 348 are made of a conductive material, such as an alloy material (e.g., a solder material), in accordance with some embodiments. The solder material includes Tin (Sn), in accordance with some embodiments.

Processes and materials for forming the chip package structures 200 and 400 may be similar to, or the same as, those for forming the chip package structures 100 and 300 described above. Elements designated by the same or similar reference numbers as those in FIGS. 1A to 4 have the same or similar structures and the materials. Therefore, the detailed descriptions thereof will not be repeated herein.

In accordance with some embodiments, chip package structures and methods for forming the same are provided. The methods (for forming the chip package structure) convert a portion of a semiconductor substrate adjacent to a conductive via structure into a dielectric structure, thereby electrically insulating the semiconductor substrate from a conductive bump formed over the conductive via. Therefore, the yield of the chip package structures is improved.

In accordance with some embodiments, a method for forming a chip package structure is provided. The method includes providing a semiconductor substrate, a conductive via structure, and an insulating layer. The conductive via structure passes through the semiconductor substrate, the semiconductor substrate has a front surface and a back surface opposite to the front surface, the insulating layer is over the back surface, the semiconductor substrate has a base portion and a protruding portion over the base portion, the protruding portion is between the conductive via structure and the insulating layer, and a first end surface of the conductive via structure, a second end surface of the protruding portion, and a first surface of the insulating layer are substantially level with each other. The method includes converting the protruding portion into a dielectric structure. The dielectric structure has a higher first dielectric constant than the protruding portion. The method includes forming a conductive bump over the conductive via structure. The conductive bump is electrically connected to the conductive via structure, and the dielectric structure electrically insulates the conductive bump from the semiconductor substrate.

In accordance with some embodiments, a method for forming a chip package structure is provided. The method includes providing a semiconductor substrate, a first conductive via structure, and a second conductive via structure. The first conductive via structure and the second conductive via structure pass through the semiconductor substrate, the semiconductor substrate has a base portion and a protruding portion over the base portion and surrounding the first conductive via structure, and the second conductive via structure is longer than the first conductive via structure. The method includes forming an insulating layer over the semiconductor substrate, the first conductive via structure, and the second conductive via structure. The method includes removing top portions of the insulating layer, the protruding portion, the first conductive via structure, and the second conductive via structure. The method includes converting the protruding portion into a dielectric structure. The dielectric structure has a higher first dielectric constant than the protruding portion.

In accordance with some embodiments, a chip package structure is provided. The chip package structure includes a semiconductor substrate having a front surface and a back surface opposite to the front surface. The back surface has a flat portion and a sloped portion. The chip package structure includes a conductive via structure passing through the semiconductor substrate. The sloped portion is between the conductive via structure and the flat portion. The chip package structure includes a dielectric structure over the sloped portion and the flat portion. The chip package structure includes an insulating layer over the dielectric structure, wherein a first end surface of the conductive via structure, a second end surface of the dielectric structure, and a first surface of the insulating layer are substantially level with each other. The chip package structure includes a conductive bump over the conductive via structure. The conductive bump is electrically connected to the conductive via structure, and the dielectric structure electrically insulates the conductive bump from the semiconductor substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a chip package structure, comprising:
providing a semiconductor substrate, a conductive via structure, and an insulating layer, wherein the conductive via structure passes through the semiconductor substrate, the semiconductor substrate has a front surface and a back surface opposite to the front surface, the insulating layer is over the back surface, the semiconductor substrate has a base portion and a protruding portion over the base portion, the protruding portion is between the conductive via structure and the insulating layer, and a first end surface of the conductive via structure, a second end surface of the protruding portion, and a first surface of the insulating layer are substantially level with each other;
converting the protruding portion into a dielectric structure, wherein the dielectric structure has a higher first dielectric constant than the protruding portion; and
forming a conductive bump over the conductive via structure, wherein the conductive bump is electrically connected to the conductive via structure, and the dielectric structure electrically insulates the conductive bump from the semiconductor substrate.

2. The method for forming the chip package structure as claimed in claim 1, wherein a width of the protruding portion of the semiconductor substrate increases toward the base portion of the semiconductor substrate.

3. The method for forming the chip package structure as claimed in claim 1, wherein the converting of the protruding portion into the dielectric structure further comprises:
converting a top part of the base portion of the semiconductor substrate into the dielectric structure.

4. The method for forming the chip package structure as claimed in claim 1, wherein the dielectric structure comprises a first dielectric layer and a second dielectric layer between the first dielectric layer and the insulating layer.

5. The method for forming the chip package structure as claimed in claim 4, wherein the second dielectric layer conformally covers a second surface of the insulating layer.

6. The method for forming the chip package structure as claimed in claim 4, wherein the second dielectric layer has a higher second dielectric constant than the first dielectric layer.

7. The method for forming the chip package structure as claimed in claim 6, wherein the second dielectric layer is thinner than the first dielectric layer.

8. The method for forming the chip package structure as claimed in claim 1, further comprising:
forming a capacitor over the front surface of the semiconductor substrate, wherein the conductive via structure is electrically connected to the capacitor.

9. The method for forming the chip package structure as claimed in claim 1, wherein the converting of the protruding portion comprises:
performing a diffusion process or an implantation process over the semiconductor substrate.

10. The method for forming the chip package structure as claimed in claim 1, further comprising:
providing a dielectric layer between the semiconductor substrate and the conductive via structure, wherein the dielectric layer separates the conductive via structure from the dielectric structure.

11. A method for forming a chip package structure, comprising:
providing a semiconductor substrate, a first conductive via structure, and a second conductive via structure, wherein the first conductive via structure and the second conductive via structure pass through the semiconductor substrate, the semiconductor substrate has a base portion and a protruding portion over the base portion and surrounding the first conductive via structure, and the second conductive via structure is longer than the first conductive via structure;
forming an insulating layer over the semiconductor substrate, the first conductive via structure, and the second conductive via structure;
removing top portions of the insulating layer, the protruding portion, the first conductive via structure, and the second conductive via structure; and
converting the protruding portion into a dielectric structure, wherein the dielectric structure has a higher first dielectric constant than the protruding portion.

12. The method for forming the chip package structure as claimed in claim 11, wherein the semiconductor substrate has a front surface and a back surface opposite to the front surface, and the second conductive via structure has a convex surface facing away from the front surface before the top portions of the insulating layer, the protruding portion, the first conductive via structure, and the second conductive via structure are removed.

13. The method for forming the chip package structure as claimed in claim 11, wherein the first conductive via structure is closer to the dielectric structure than the second conductive via structure.

14. The method for forming the chip package structure as claimed in claim 11, wherein the dielectric structure is wider than the first conductive via structure.

15. The method for forming the chip package structure as claimed in claim 11, wherein the dielectric structure has an L-like shape.

16. A chip package structure, comprising:
a semiconductor substrate having a front surface and a back surface opposite to the front surface, wherein the back surface has a flat portion and a sloped portion;
a conductive via structure passing through the semiconductor substrate, wherein the sloped portion is between the conductive via structure and the flat portion;
a dielectric structure over the sloped portion and the flat portion;
an insulating layer over the dielectric structure, wherein a first end surface of the conductive via structure, a second end surface of the dielectric structure, and a first surface of the insulating layer are substantially level with each other; and
a conductive bump over the conductive via structure, wherein the conductive bump is electrically connected to the conductive via structure, and the dielectric structure electrically insulates the conductive bump from the semiconductor substrate.

17. The chip package structure as claimed in claim 16, wherein the conductive bump is over the second end surface of the dielectric structure.

18. The chip package structure as claimed in claim 16, wherein the dielectric structure comprises a first dielectric layer and a second dielectric layer between the first dielectric layer and the insulating layer.

19. The chip package structure as claimed in claim 18, wherein the second dielectric layer has a higher dielectric constant than the first dielectric layer.

20. The chip package structure as claimed in claim 18, further comprising:
a molding layer surrounding the semiconductor substrate.
